(19) United States
(12) Patent Application Publication
(10) Pub. No.: US 2025/0259943 A1
(43) Pub. Date: Aug. 14, 2025

(54) DIE SHAPE CONTROL FOR DIE TO WAFER BOND ENHANCEMENT

(71) Applicant: Tokyo Electron Limited, Tokyo (JP)

(72) Inventors: Anthony R. SCHEPIS, Averill Park, NY (US); David POWER, Saratoga Springs, NY (US); David CONKLIN, Saratoga Springs, NY (US); Anton J. DEVILLIERS, Clifton Park, NY (US)

(73) Assignee: Tokyo Electron Limited, Tokyo (JP)

(21) Appl. No.: 18/440,435

(22) Filed: Feb. 13, 2024

(51) Int. Cl. H01L 23/00; H01L 21/66; H01L 21/78

(52) U.S. Cl. CPC H01L 23/562; H01L 21/78; H01L 22/12

(57) ABSTRACT

Aspects of the present disclosure provide a die-to-wafer (D2W) shape correction and bonding method. For example, the method can include providing a wafer and a chiplet, forming a shape control layer on at least one of the wafer and the chiplet, activating the shape control layer according to a bow measurement of the at least one of the wafer and the chiplet to modify an internal stress of the shape control layer, and bonding the wafer and the chiplet, at least one of which has the shape control layer formed thereon that is activated according to the bow measurement of the at least one of the wafer and the chiplet.

### FIELD OF THE INVENTION

The present disclosure relates to semiconductor fabrication, and, more particularly, to wafer-to-wafer bonding and die-to-wafer bonding.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

With the advent of three-dimensional (3D) packaging, the semiconductor industry is entering a critical juncture where traditional die to wafer bonding based alignment corrections are not able to account for the non-linear physical effects induced via processing. That is to say, the stressors enacted on the wafer prior to the die to wafer bonding operation impart chiplet specific localized shape distortions that cause alignment failures and can compromise critical bonding metrics, directly resulting in significant yield losses in advanced packaging processes. These yield losses will only continue to be exacerbated as alignment tolerances shrink in the next generation chip designs of advanced node semiconductor manufacturing.

### SUMMARY

Aspects of the present disclosure provide a die-to-wafer (D2W) shape correction and bonding method. For example, the method can include providing a wafer and a chiplet, forming a shape control layer on at least one of the wafer and the chiplet, activating the shape control layer according to a bow measurement of the at least one of the wafer and the chiplet to modify an internal stress of the shape control layer, and bonding the wafer and the chiplet, at least one of which has the shape control layer formed thereon that is activated according to the bow measurement of the at least one of the wafer and the chiplet.

In an embodiment, the method can further include receiving the bow measurement of the at least one of the wafer and the chiplet. In another embodiment, the method can further include measuring the at least one of the wafer and the chiplet to identify the bow measurement of the at least one of the wafer and the chiplet. For example, measuring the at least one of the wafer and the chiplet to identify the bow measurement of the at least one of the wafer and the chiplet can include measuring the at least one of the wafer and the chiplet with the shape control layer formed thereon to identify the bow measurement of the at least one of the wafer and the chiplet with the shape control layer formed thereon.

In an embodiment, forming the shape control layer on at least one of the wafer and the chiplet can include forming a wafer shape control layer on the wafer and forming a chiplet shape control layer on the chiplet, and activating the shape control layer according to a bow measurement of the at least one of the wafer and the chiplet to modify an internal stress of the shape control layer can include activating the wafer shape control layer according to a bow measurement of the wafer to modify an internal stress of the wafer shape control layer and activating the chiplet shape control layer according to a bow measurement of the chiplet to modify an internal stress of the chiplet shape control layer.

In an embodiment, the method can further include singulating another wafer to obtain the chiplet. For example, forming the shape control layer on at least one of the wafer and the chiplet can include forming another shape control layer on the another wafer, and singulating the another wafer to obtain the chiplet can include singulating another wafer with the another shape control layer formed thereon to obtain the chiplet with the shape control layer formed thereon, the shape control layer being singulated from the another shape control layer.

In an embodiment, the shape control layer can be formed on at least one of a frontside surface and a backside surface of the at least one of the wafer and the chiplet. For example, the shape control layer can be formed on the backside surface of the at least one of the wafer and the chiplet.

In an embodiment, the shape control layer can include an any combination of oxide and nitride. In another embodiment, the shape control layer can include an organic spin-on material.

In an embodiment, the shape control layer can include a heat sensitive material and be activated by a pattern of heat that corresponds to the bow measurement of the at least one of the wafer and the chiplet. For example, the pattern of heat can be generated via direct laser write. As another example, the pattern of heat can be generated by a plurality of heating units that have an arrangement corresponding to the pattern of heat and generate different temperature ranges.

In another embodiment, the shape control layer can include a photosensitive material and be activated by actinic radiation, patterning and etching, the patterning corresponding to the bow measurement of the at least one of the wafer and the chiplet. For example, the actinic radiation can provide localized heating that corresponds to the bow measurement of the at least one of the wafer and the chiplet.

Aspects of the present disclosure provide another D2W shape correction and bonding method. For example, the method can include providing a wafer and a chiplet, at least one of which has an integrated layer formed thereon, the integrated layer having a thermal characteristic that is sufficient to execute shape manipulation on the at least one of the wafer and the chiplet when employing a temperature type activation. The method can also include applying the temperature type activation to the integrated layer according to a bow measurement of the at least one of the wafer and the chiplet to execute the shape manipulation on the at least one of the wafer and the chiplet, and bonding the wafer and the chiplet.

Note that this summary section does not specify every embodiment and/or

incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements, and wherein:

FIGS. 1A to 1C show first and second order bowing of a wafer;

FIGS. 2A and 2B show low order global wafer distortion and high order local wafer distortion, respectively;

FIG. 3 shows chiplet level localized distortion post singulation;

FIG. 4 is a plan view of an exemplary wafer processing system for correcting or modifying wafer bow in accordance with some embodiments of the present disclosure;

FIG. 5 is a flow of an exemplary D2W shape correction and bonding method according to some embodiments of the present disclosure; and

FIGS. 6A to 6F illustrate a flow of an exemplary method for applying and activating a shape control layer according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

The present disclosure provides the industry a much needed solution to combat process induced wafer/chiplet (wafer/die) distortion and enable the future of die-to-wafer (D2W) packaging solutions. Aspects of the present disclosure provide a method to manipulate die and or wafer shape via a stress control layer(s). The stress control layer(s) may be locally augmented by patterning and/or activation processes to enhance the degrees of freedom. Wafer shape metrology standard to the semiconductor industry can be used as an input function to engineer the correct stress of the control layer(s) and optimize augmentation locations such that D2W bonding performance is enhanced. Integration of this intellectual property (IP) can result in reduced D2W bonding overlay residual, improved bond strength and curtailed voiding, providing a commensurate yield increase.

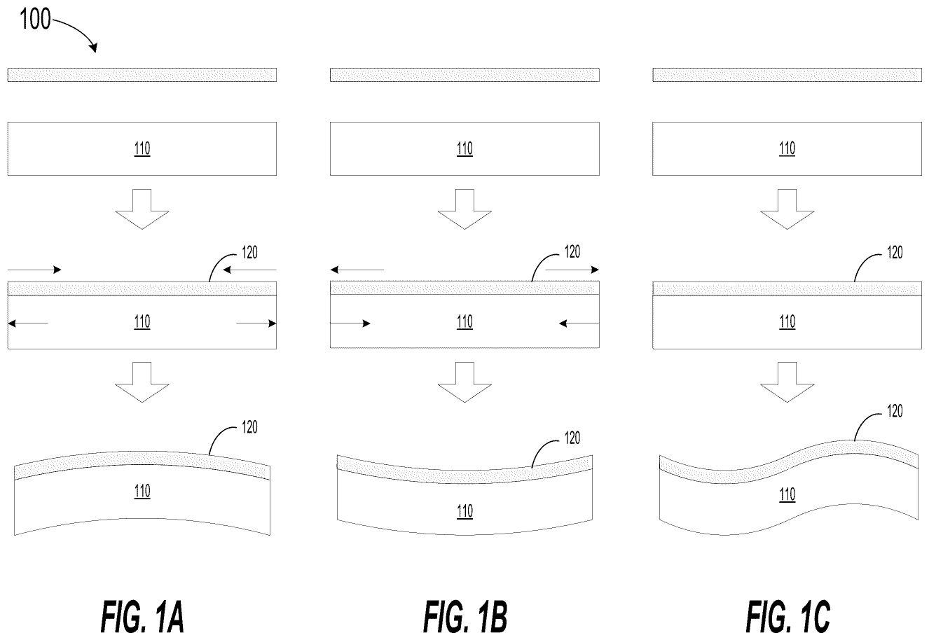

A functional semiconductor wafer can be comprised of the integration of 70+ individual layers that ultimately culminate in functional devices. Each level requires multiple processing steps including, but not limited to thin film deposition, lithography and etches to form the desired structures. For example, microfabrication of a semiconductor structure 100 begins with a flat substrate or wafer 110, as those illustrated in FIGS. 1A to IC. During microfabrication of the semiconductor structure 100, multiple processing steps are executed that can include depositing material on the wafer 110, removing material, implanting dopants, annealing, baking, and so forth. Different materials and structural formations 120 thus formed can induce non-uniform wafer stresses, which result in bowing of the semiconductor structure 100, which in turn affects overlay and typically results in overlay errors of various magnitudes.

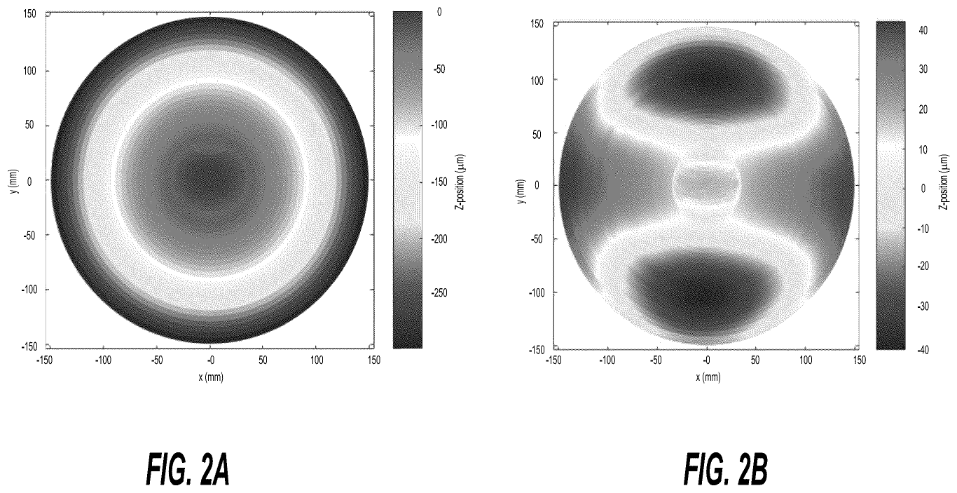

For example, FIGS. 1A and 1B show how the different materials and structural formations 120 can either induce a compressive or tensile stress in the wafer 110, respectively, resulting in first order bowing with bow measurements illustrating z-direction height (or z-height) deviations from a reference plane (not shown). As another example, FIG. IC shows second order bowing of the wafer 110 with two bow measurements identifying positive and negative z-height deviations, respectively. The non-uniform wafer stresses fundamentally distort the wafer grid. These distortions can manifest as low order global spherical type deformations as depicted in FIG. 2A, which shows z-height variations on 300 nm semiconductor wafers. Higher order localized z-height variations may exist as stand-alone distortions or may be embedded in the global signature. An example of a higher order wafer deformation is presented in FIG. 2B. The data presented is derived from standard semiconductor metrology equipment common to the industry. Both low and high order wafer shapes can complicate the D2W bonding process and negatively impact yield.

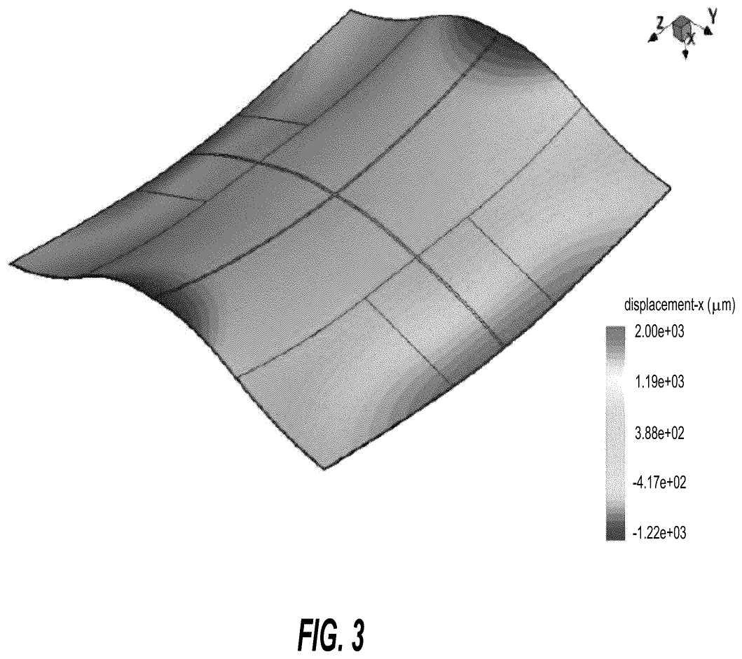

Once the semiconductor structure 100 has been fully formed at the wafer level, it needs to be released from the bulk substrate to create individual chiplets that can be packaged. Typically, the semiconductor structure 100 can contain 100s of individual chips formed across the substrate 110. As one can imagine, the unique stress profile generated at the wafer level redistributes amongst the chiplets in a location specific manor once released from the bulk substrate, generating a several order of magnitude increase in specific shape profiles. An example of a die-level localized distortion post singulation is shown in FIG. 3.

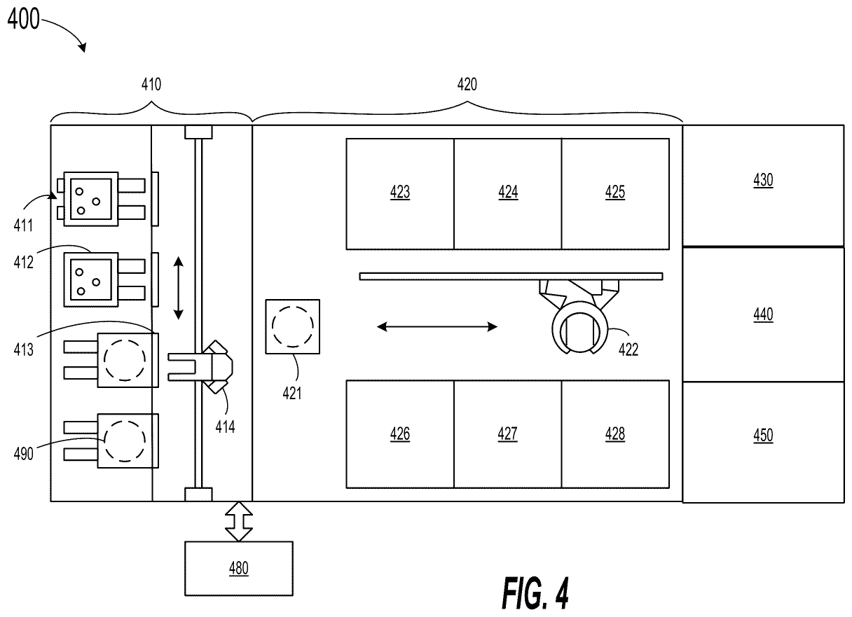

FIG. 4 is a plan view of an exemplary wafer processing system 400, e.g., a track lithography tool, for correcting or modifying wafer (and die or chiplet) bow in accordance with some embodiments of the present disclosure. The wafer processing system 400 includes various wafer handling components or carriers, along with several stages, e.g., a carrier stage 410 and a treatment stage 420. The carrier stage 410 includes one or more pod assemblies 411 that are configured to receive one or more wafer cassettes 412 that are configured to contain one or more wafers 490, e.g., the wafer 110 shown in FIGS. 1A to 1C, that are to be processed in the wafer processing system 400. In an embodiment, the wafer cassettes 412 can be further configured to accept already diced chiplets stored on either tape or frame. Doors 413 can open to access the wafers 490 contained in the wafer cassettes 412. A carrier transfer robot 414 can move up and down and transfer the wafers 490 from the wafer cassettes 412 to a shelf unit 421 that is installed in the treatment stage 420 for storing the wafers 490 temporarily.

The treatment stage 420 includes a variety of treatment modules, e.g., treatment modules 423-428, and a treatment transfer robot 422. The treatment transfer robot 422 is configured to access the shelf unit 421 and the treatment modules 423-428 and transfer the wafers 490 among the treatment modules 423-428 for various processing. In an embodiment, the treatment transfer robot 422 can flip and rotate the wafers 490. The modules 423-428 can include one or more metrology modules 423, which are configured to measure an amount of wafer bow of the wafers 490 and provide bow measurements to the wafer processing system 400. In an embodiment, the metrology modules 423 can use optical (e.g., using a scanning laser technique), acoustic and other mechanisms to measure the z-height deviations across a surface of the wafer and store the height deviations by (x, y) coordinates to identify a plurality of sub-bow measurements (x, y) of the bow measurement. Bow measurements can include measuring a degree of convexity or concavity, or mapping z-height deviation values on the wafers 490 relative to one or more reference z-height deviation values. In other words, z-height deviation values are spatially mapped, such as with coordinate locations, to identify z-height deviation values across a surface of the wafer 490. Bow measurements and z-height deviation values can be mapped at various resolutions depending on types of metrology equipment used and/or a resolution desired. In an embodiment, the metrology modules 423 can also measure the amount of die bow of each of dies obtained by dicing and singulating the wafer 490.

The bow (and die) measurements can include raw bow data or be represented as a bow signature with relative z-height deviation values. In many embodiments, the reference z-height deviation values may be all close to zero and thus representative of a wafer that is close to being flat. For example, a wafer that is close to being flat or considered flat for overlay improvement herein can be a wafer having an average z-height deviation value of less than 1 μm. In some embodiments, the reference z-height deviation values can represent some non-planar shape, but which shape is, notwithstanding, useful for overlay error correction—especially for particular stages of micro fabrication. Techniques herein enable correction of bowing that is greater than 1 μm, for example. The metrology module 423 is configured to measure the wafer 490, which has a working surface and a backside surface opposite to the working surface. The wafer 490 may have an initial wafer bow value resulting from one or more micro fabrication processing steps that have been executed to create at least part of a semiconductor device on the working surface of the wafer 490. For example, field-effect transistors (FETs) may be completed or only partially completed on the working surface of the wafer 490.

The treatment modules 423-428 can also include one or more film formation modules 424 that are configured to form one or more films, e.g., a shape control layer, on a surface of the wafer 490 being processed. The film formation module 424 can be configured to deposit a shape control layer on the frontside and/or backside surface of the wafer 490 using chemical vapor deposition, atomic layer deposition, spin-on film deposition process, or other deposition techniques. For example, in the spin-on film deposition an amount of a shape control material is deposited on the backside surface of the wafer 490 while the wafer 490 is rotating, thus causing a solvent in the shape control material to evaporate and the properties of the deposited shape material to change, to promote the adhesion of the shape control material to the backside surface of the wafer 490. The shape control material can be any combination of films such as oxides, nitrides and/or spin-on films present on the backside surface of the wafer 490. In an embodiment, the film formation module 424 can further perform a lithographic process on the shape control material. For example, the lithographic process can include depositing and forming a resist layer on the shape control material, exposing the resist layer to radiation or heat, developing a portion of the resist layer that has been exposed to the radiation, transferring the pattern of the remaining resist layer to the shape control material by etching the shape control material to form the shape control layer, and removing the remaining resist layer. The film formation module 424 and the metrology module 423 can be installed on a common platform having an automated wafer handling system that automatically moves the wafer 490 from the metrology module 423 to the film formation module 424.

In an embodiment, the shape control material can include a heat sensitive material, which, when reactive to heat, may have its internal stress modified by the heat to become compressive, neutral or tensile. In another embodiment, the shape control material can include a photosensitive material, which, when exposed to actinic radiation or light, absorbs light in the desired or required energy spectrum and exhibits a chemical/physical reaction that allows applications at different fields.

The treatment modules 423-428 can also include one or more bake modules 425 that are configured to bake the wafer 490 to a target temperature. For example, the bake module 425 can bake and stabilize the wafer 490 at 32° C. or 90° C. As another example, the bake module 425 can bake the wafer 490 with a shape control material (e.g., a heat sensitive material) formed thereon using a pattern of heat that correspond to a bow measurement of the wafer 490, to correct or modify an internal stress of the shape control layer. The treatment modules 423-428 can also include one or more radiation sources 426 that are configured to project onto different regions of the shape control material radiations of variable intensities that correspond to the bow measurement of the wafer 490. The treatment modules 423-428 can also include a plurality of heating units 427, which can be installed on a wafer chuck that is used for a wafer to be placed thereon. The heating units 427 can have an arrangement corresponding to a certain pattern of heat and generate different temperature ranges of heat, and the wafer chuck can thus have a plurality of heating zones that correspond to the certain pattern of heat. Accordingly, the shape control material can be heated in different regions that correspond to the certain pattern of heat such that the stresses of the shape control material combined with the wafer in the different regions can be modified to become compressive, neutral or tensile.

The wafer processing system 400 further includes a controller 480. The controller 480 can be a computer processor located within the wafer processing system 400, or located remotely but being in communication with components, e.g., the metrology module 423, the film formation module 424, the bake module 425, the radiation source 426 and the heating units 427, of the wafer processing system 400. In an embodiment, the controller 480 is configured to control the metrology module 423 to measure a wafer 490 to identify a bow measurement of the wafer 490 (and/or measure a die to identify a bow measurement of the die), receive the bow measurement from the metrology module 423, control the film formation module 424 to form a shape control layer on the backside (or frontside or both) surface of the wafer 490, control the bake module 425 to differentially bake the wafer 490 with the shape control layer formed thereon using a pattern of heat that corresponds to the bow measurement of the wafer 490, control the radiation source 426 to project on different regions of the shape control layer radiations of variable intensities that correspond to the bow measurement of the wafer 490 and/or control the heating units 427 to generate different temperature ranges of heat that correspond to the a certain pattern of heat, to correct or modify the internal stress of the stressor film. The film formation module 424, the bake module 425 and the controller 480 can be referred to as a wafer processing device.

The wafer processing system 400 can also include other stages or components, e.g., a stepper/scanner 430, a singulation device 440 and a bonding tool 450. In an embodiment, the stepper/scanner 430 can be detached from the treatment stage 420 since the throughput of the stepper/scanner 430 is often many times greater than the throughput of the carrier stage 410 and the treatment stage 420, and thus dedicating the stepper/scanner 430 to a single treatment stage wastes the stepper/scanner's excess throughput capacity. The singulation device 440 can be configured to dice and singulate a wafer, with or without a shape control layer formed thereon, to obtain a plurality of chiplets. The bonding tool 450 is configured to connect (join) an integrated chiplet (or die or wafer) with a wafer together in one mechanically stable package. The bonding tool 450 can employ direct wafer bonding (such as fusion bonding and anodic bonding) or wafer bonding with intermediate material (such as solder bonding and cutectic bonding) to bond a wafer/chiplet with a wafer/chiplet. As such, a D2W bonding platform consists of handling mechanisms and process modules for the chiplet and the wafer. In the example embodiment shown in FIG. 4, the film formation module 424, the bake module 425, the radiation source 426 and the heating units 427 that perform the shape control process are integrated as a standalone platform. In another embodiment, one or more of the film formation module 424, the bake module 425, the radiation source 426 and the heating units 427 can be integrated into the bonding tool 450.

The types of shape distortions shown in the die (FIG. 3) and the wafer (FIGS. 2A and 2B) of the D2W bonding process result in residual errors that are uncorrectable by the construct of the D2W bonding system. As understood by those familiar in the art, if these residual overlay errors are large enough in magnitude, they can create critical failures in electrical continuity causing the device not to yield. It is therefore paramount that a technology exists to manipulate die and wafer shape favorably to provide a compensation mechanism for the deficiencies present in the D2W bonder's alignment system that are unable to address the grid distortion effectively. This is especially true as the semiconductor enters a critical juncture with the advent of 3D packaging and shrinking alignment tolerances of next generation device designs.

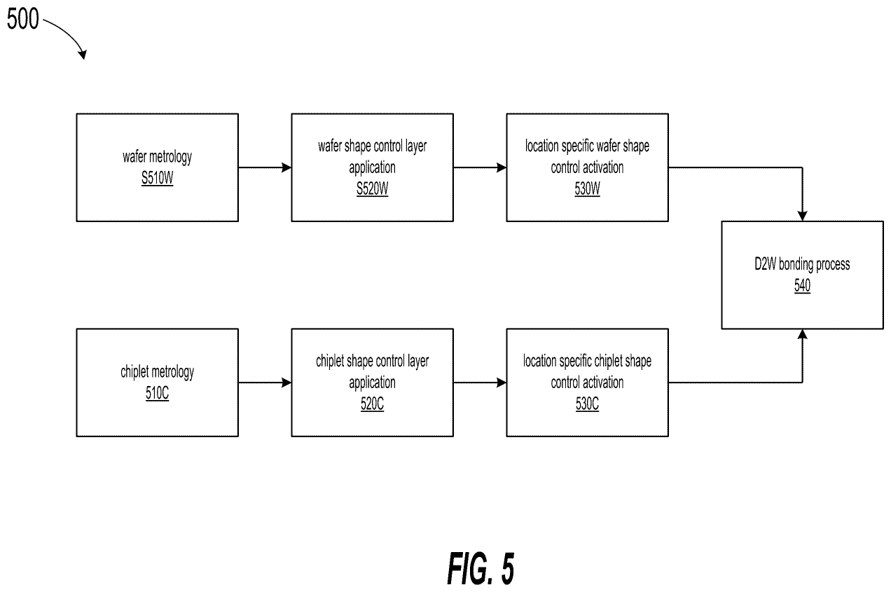

FIG. 5 is a flow of an exemplary D2W shape correction and bonding method 500 according to some embodiments of the present disclosure. The method 500 is proposed to correct the shape distortions of one or more chiplets (or dies or a wafer) to a wafer and bond the chiplets to the wafer. The chiplet, the wafer, or both, intended for bonding, would undergo shape metrology to record their distortion signatures. This shape metrology may be supported virtually and/or enhanced via complimentary simulation and at multiple points in the flow. Although the depicted flow executes shape metrology sequentially prior to shape control layer application(s), this data may be collected at a previous point in the line and fed forward. The method 500 can include steps S510W, S520W and S530W and/or steps S510C, S520C and S530C, and step S540. The method 500 starts with steps S510W and S510C, which can be executed simultaneously or sequentially.

At step S510W, shape metrology is performed on a wafer to obtain the bow measurement of the wafer. For example, the metrology modules 423 can be used to measure an amount of wafer bow of the wafer and provide the bow measurements to the wafer processing system 400. Similarly, at step S510C, shape metrology is performed on at least one chiplet that is to be bonded to the wafer to obtain the bow measurement of the chiplet. For example, the metrology modules 423 can be used to measure an amount of chiplet bow of the chiplet and provide the bow measurements to the wafer processing system 400. The method 500 can proceed to steps S520W and S520C.

At step S520W, a wafer shape control layer is deposited and formed on a backside and/or frontside surface of the wafer. For example, the film formation module 424 can be used to deposit and form the wafer shape control layer on the backside surface of the wafer using chemical vapor deposition, atomic layer deposition, spin-on film deposition process, or other deposition techniques. Similarly, at step S520C, a chiplet shape control layer is deposited and formed on a backside and/or frontside surface of the chiplet. For example, the film formation module 424 can be used to deposit and form the chiplet shape control layer on the backside surface of the chiplet. In the example embodiment shown in FIG. 5, the method 500 exhibits the application of the (wafer and chiplet) shape control layers proceeding shape metrology. In an embodiment, these shape control layers can be applied before shape metrology, which means that the metrology module 423 measures an amount of bow of the wafer (chiplet) with the wafer (chiplet) shape control layer already formed on the backside surface thereof. In another embodiment, these shape control layers may be optional depending on the activation mechanism. For example, the thermal characteristics of the existing integrated layers from the device (e.g., the wafer and/or the chiplet) may be sufficient to execute shape manipulation via expansion when employing a temperature type activation that corresponds to the bow measurement of the wafer and/or the chiplet. In the example embodiment shown in FIG. 5, the application of the chiplet shape control layer happens post singulation. In some embodiments, the application of the chiplet shape control layer can happen pre signulation. That is to say, the chiplet shape control layer can be applied at the wafer level with the anticipation of facilitating chiplet level manipulations post singulation. The method 500 can proceed to steps S530W and S530C.

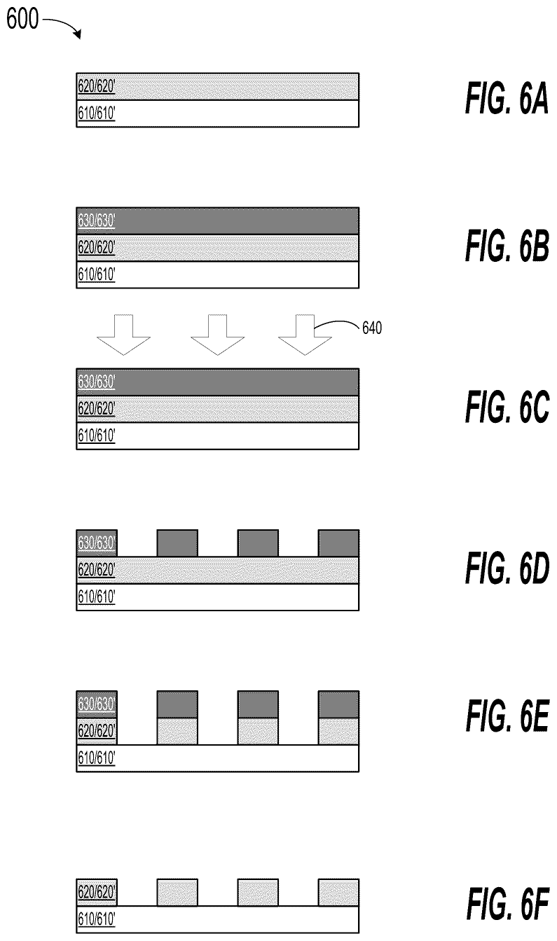

At step S530W, location specific shape control is activated for the wafer shape control layer. For example, the wafer shape control layer can include a heat sensitive material, and the bake module 425 can be used to bake the wafer with the wafer shape control layer (e.g., a heat sensitive material) formed thereon using a pattern of heat that correspond to a bow measurement of the wafer, to correct or modify an internal stress of the wafer shape control layer. As another example, the wafer shape control layer can include a photosensitive material, and the radiation source 426 can be used to project onto different regions of the wafer shape control layer radiations of variable intensities that correspond to the bow measurement of the wafer. In some embodiments, the wafer shape control layer can include any combination of films such as oxides, nitrides and/or spin-on films, and the film formation module 424 can be used to perform a lithographic process on the wafer shape control material to form the wafer shape control layer. For example, the film formation module 424 can be used to deposit and form a wafer shape control layer 620 on a wafer 610 (as shown in FIG. 6A), deposit and form a resist (photoresist) layer 630 on the wafer shape control layer 620 (as shown in FIG. 6B), exposing the resist layer 630 to radiation 640 (as shown in FIG. 6C) that corresponds to the bow measurement of the wafer, removing a portion of the resist layer 630 that has been exposed to the radiation 640 (as shown in FIG. 6D), transferring the pattern of the remaining resist layer 630 to the wafer shape control layer 620 by etching the wafer shape control layer 620 to form the patterned wafer shape control layer 620 that corresponds to the bow measurement of the wafer (as shown in FIG. 6E), and removing the remaining resist layer 630 (as shown in FIG. 6F). Therefore, the wafer with the patterned wafer shape control layer 620 formed thereon can have its shape distortion corrected.

At step S530C, location specific shape control is activated for the chiplet shape control layer. For example, the chiplet shape control layer can include a heat sensitive material, and the bake module 425 can be used to bake the wafer with the chiplet shape control layer (e.g., a heat sensitive material) formed thereon using a pattern of heat that correspond to a bow measurement of the chiplet, to correct or modify an internal stress of the chiplet shape control layer. In an embodiment, a heater, e.g., the bake module 425, can be integrated into the bond head and configured to heat and shape the chiplet shape control layer as the chiplet attaches to the wafer. As another example, the chiplet shape control layer can include a photosensitive material, and the radiation source 426 can be used to project onto different regions of the chiplet shape control layer radiations of variable intensities that correspond to the bow measurement of the chiplet. In an embodiment, any of the modules relating to heat shaping/bonding, e.g., the bake module 425, the radiation source 426 and the bond head, can occur in a vacuum environment. In some embodiments, the chiplet shape control layer can include any combination of films such as oxides, nitrides and/or spin-on films, and the film formation module 424 can be used to perform a lithographic process on the chiplet shape control layer to form the chiplet shape control layer. For example, the film formation module 424 can be used to deposit and form a chiplet shape control layer 620′ on a chiplet 610′ (as shown in FIG. 6A), deposit and form a resist (photoresist) layer 630′ on the chiplet shape control layer 620′ (as shown in FIG. 6B), exposing the resist layer 630′ to radiation 640 (as shown in FIG. 6C) that corresponds to the bow measurement of the chiplet, removing a portion of the resist layer 630′ that has been exposed to the radiation 640 (as shown in FIG. 6D), transferring the pattern of the remaining resist layer 630′ to the chiplet shape control layer 620′ by etching the chiplet shape control layer 620′ to form the patterned chiplet shape control layer 620′ that corresponds to the bow measurement of the chiplet (as shown in FIG. 6E), and removing the remaining resist layer 630′ (as shown in FIG. 6F). Therefore, the chiplet with the patterned chiplet shape control layer 620′ formed thereon can have its shape distortion corrected. The method 500 can proceed to step S540.

At step S540, the bonding tool 450 can be used to perform a D2W process to bond the wafer with the chiplet, either or both of which have their bow measurements modified and corrected by the wafer shape control layer and the chiplet shape control layer, respectively. For example, the bonding tool 450 can be used to employ direct wafer bonding or wafer bonding with intermediate material to bond the wafer with the chiplet. With optimized shape, the compensated chiplet and wafer would then continue their normal integrated flow through the D2W bonding process resulting in samples that result in improved bonding metrics that would otherwise have been unachieved using the standard tooling/process.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a dielectric layer on or overlying a base substrate structure such as a thin film. Thus, substrate is not limited to any particular base structure, underlying dielectric layer or overlying dielectric layer, patterned or un-patterned, but rather, is contemplated to include any such dielectric layer or base structure, and any combination of dielectric layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method, comprising:
providing a wafer and a chiplet;
forming a shape control layer on at least one of the wafer and the chiplet;
activating the shape control layer according to a bow measurement of the at least one of the wafer and the chiplet to modify an internal stress of the shape control layer; and
bonding the wafer and the chiplet, at least one of which has the shape control layer formed thereon that is activated according to the bow measurement of the at least one of the wafer and the chiplet.

2. The method of claim 1, further comprising:
receiving the bow measurement of the at least one of the wafer and the chiplet.

3. The method of claim 1, further comprising:
measuring the at least one of the wafer and the chiplet to identify the bow measurement of the at least one of the wafer and the chiplet.

4. The method of claim 3, wherein measuring the at least one of the wafer and the chiplet to identify the bow measurement of the at least one of the wafer and the chiplet includes measuring the at least one of the wafer and the chiplet with the shape control layer formed thereon to identify the bow measurement of the at least one of the wafer and the chiplet with the shape control layer formed thereon.

5. The method of claim 1, wherein
forming the shape control layer on at least one of the wafer and the chiplet includes forming a wafer shape control layer on the wafer and forming a chiplet shape control layer on the chiplet, and
activating the shape control layer according to a bow measurement of the at least one of the wafer and the chiplet to modify an internal stress of the shape control layer includes activating the wafer shape control layer according to a bow measurement of the wafer to modify an internal stress of the wafer shape control layer and activating the chiplet shape control layer according to a bow measurement of the chiplet to modify an internal stress of the chiplet shape control layer.

6. The method of claim 1, further comprising:
singulating another wafer to obtain the chiplet.

7. The method of claim 6, wherein
forming the shape control layer on at least one of the wafer and the chiplet includes forming another shape control layer on the another wafer, and
singulating the another wafer to obtain the chiplet includes singulating another wafer with the another shape control layer formed thereon to obtain the chiplet with the shape control layer formed thereon, the shape control layer being singulated from the another shape control layer.

8. The method of claim 1, wherein the shape control layer is formed on at least one of a frontside surface and a backside surface of the at least one of the wafer and the chiplet.

9. The method of claim 8, wherein the shape control layer is formed on the backside surface of the at least one of the wafer and the chiplet.

10. The method of claim 1, wherein the shape control layer includes an any combination of oxide and nitride.

11. The method claim 1, wherein the shape control layer includes an organic spin-on material.

12. The method of claim 1, wherein the shape control layer includes a heat sensitive material and is activated by a pattern of heat that corresponds to the bow measurement of the at least one of the wafer and the chiplet.

13. The method of claim 12, wherein the pattern of heat is generated via direct laser write.

14. The method of claim 12, wherein the pattern of heat is generated by a plurality of heating units that have an arrangement corresponding to the pattern of heat and generate different temperature ranges.

15. The method of claim 1, wherein the shape control layer includes a photosensitive material and is activated by actinic radiation, patterning and etching, the patterning corresponding to the bow measurement of the at least one of the wafer and the chiplet.

16. The method of claim 15, wherein the actinic radiation provides localized heating that corresponds to the bow measurement of the at least one of the wafer and the chiplet.

17. A method, comprising:
providing a wafer and a chiplet, at least one of which has an integrated layer formed thereon, the integrated layer having a thermal characteristic that is sufficient to execute shape manipulation on the at least one of the wafer and the chiplet when employing a temperature type activation;
applying the temperature type activation to the integrated layer according to a bow measurement of the at least one of the wafer and the chiplet to execute the shape manipulation on the at least one of the wafer and the chiplet; and
bonding the wafer and the chiplet.

18. The method of claim 17, further comprising:
receiving the bow measurement of the at least one of the wafer and the chiplet.

19. The method of claim 18, further comprising:
measuring the at least one of the wafer and the chiplet to identify the bow measurement of the at least one of the wafer and the chiplet.

20. The method of claim 19, wherein measuring the at least one of the wafer and the chiplet to identify the bow measurement of the at least one of the wafer and the chiplet includes measuring the at least one of the wafer and the chiplet having the integrated layer formed thereon to identify the bow measurement of the at least one of the wafer and the chiplet having the integrated layer formed thereon.
